(19) United States
(12) Patent Application Publication
(10) Pub. No.: US 2023/0032165 A1
(43) Pub. Date: Feb. 2, 2023

(54) EDGE CONDUCTOR COATING

(71) Applicant: Corning Incorporated, Corning, NY (US)

(72) Inventors: David Lynn Baker, Painted Post, NY (US); Sean Matthew Garner, Elmira, NY (US); Christina Marie Laskowski, Painted Post, NY (US); Kevin Ray Maslin, Athens, PA (US); Michael Lesley Sorensen, Waverly, NY (US); Haregewine Tadesse, Corning, NY (US)

(21) Appl. No.: 17/787,457

(22) PCT Filed: Jan. 13, 2021
(86) PCT No.: PCT/US2021/013148

§ 371 Date: Jun. 20, 2022

Related U.S. Application Data
(60) Provisional application No. 62/966,286, filed on Jan. 27, 2020.

(51) Int. Cl. H05K 1/11

(52) U.S. Cl. CPC H05K 1/117; H05K 2201/10128

(57) ABSTRACT

An edge conductor includes a first portion electrically connected to a first conductor on a first surface of a substrate, a second portion electrically connected to a second conductor on a second surface of the substrate, a third portion extending between the first portion and the second portion along an edge of the substrate, and a coating covering at least a portion of the third portion of the edge conductor, where the second surface of the substrate is opposite the first surface of the substrate, and the edge of the substrate extends between the first surface of the substrate and the second surface of the substrate.

This application claims the benefit of priority under 35 U.S.C. § 119 of U.S. Provisional Application Ser. No. 62/966,286 filed on Jan. 27, 2020, the content of which is incorporated herein by reference in its entirety.

### FIELD

The present disclosure relates generally to coating of electrical conductors. More particularly, the present disclosure relates to coating of edge conductors which electrically couple conductors on opposite surfaces of a substrate, such as a glass substrate of a display tile.

### TECHNICAL BACKGROUND

Electronic displays may be used in numerous types of devices such as smart phones, tablet computers, automotive electronics, augmented reality devices, and the like. Tiled displays, in which pixels on adjacent tiles continue at the same pitch as pixels within a tile, may be used to achieve a “zero bezel” or “seamless tiled” display. Tiled displays may include control electronics on or adjacent to one surface of a glass substrate and emitters on an opposite surface of the glass substrate.

One approach to transfer electrical signals between one surface of a glass substrate of a display tile and an opposite surface of the glass substrate may include edge conductors that extend around an edge of a glass substrate from one surface of the glass substrate to an opposite surface of the glass substrate. Such edge conductors, however, may be become damaged due to exposure and/or may impact optical characteristics of the display tile.

Accordingly, coating, at least partially or fully, of edge conductors to protect and/or conceal the edge conductors is disclosed herein.

### SUMMARY

Some embodiments of the present disclosure relate to an edge conductor. The edge conductor includes a first portion electrically connected to a first conductor on a first surface of a substrate, a second portion electrically connected to a second conductor on a second surface of the substrate, a third portion extending between the first portion and the second portion and extending along an edge of the substrate, and a coating covering at least a portion of the third portion of the edge conductor. The second surface of the substrate is opposite the first surface of the substrate, and the edge of the substrate extends between the first surface of the substrate and the second surface of the substrate.

Other embodiments of the present disclosure relate to a display tile. The display tile includes a substrate having a first surface, a second surface opposite the first surface, and an edge surface extending between the first surface and the second surface. The display tile includes a first conductor on the first surface of the substrate, a second conductor on the second surface of the substrate, and a third conductor extending along each of the first surface, the second surface, and the edge surface. The display tile includes a coating covering at least a portion of the third conductor along the edge surface. The third conductor is electrically coupled with both the first conductor and the second conductor.

Other embodiments of the present disclosure relate to a method of making a display tile. The method includes forming an edge conductor to extend along a first surface of a substrate, a second surface of the substrate opposite the first surface of the substrate, and an edge surface of the substrate, the edge surface extending between the first surface of the substrate and the second surface of the substrate. The method further includes coating at least a portion of the edge conductor along the edge surface of the substrate.

The coated edge conductors and methods disclosed herein enable the transfer of electrical signals from one surface of a glass substrate to an opposite surface of the glass substrate while protecting and/or concealing the edge conductors.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate various embodiments described herein, and together with the description serve to explain the principles and operations of the claimed subject matter.

### BRIEF DESCRIPTION OF THE DRAWINGS

FIGS. 1A, 1B schematically depict front and back plan views, respectively, of an example of a display tile.

FIG. 2 schematically depicts an exploded perspective view of an example of a substrate for a display tile with a plurality of edge conductors.

FIG. 3 schematically depicts a side view of an example of an edge conductor secured to the substrate of FIG. 2.

FIG. 4 schematically depicts a side view of an example of an edge conductor secured to the substrate of FIG. 2 with a coating over the edge conductor.

FIG. 5 schematically depicts a perspective view of an example of a substrate for a display tile with a plurality of edge conductors and a coating over the edge conductors.

FIGS. 6A, 6B, 6C schematically depict an example of spacers which may be used when applying a coating to multiple display tiles at one time.

FIGS. 7A, 7B, 7C schematically depict an example of a fixture which may be used when applying a coating to one or more display tiles.

FIGS. 8A, 8B schematically depict an example of a fixture which may be used when applying a coating to one or more display tiles.

FIGS. 9A, 9B, 9C, 9D schematically depict an example of a fixture which may be used when applying a coating to one or more display tiles.

FIG. 10 schematically depicts an example of a fixture which may be used when applying a coating to one or more display tiles.

FIG. 11 schematically depicts an example of a fixture which may be used when applying a coating to multiple display tiles.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein (for example, up, down, right, left, front, back, top, bottom, vertical, horizontal) are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

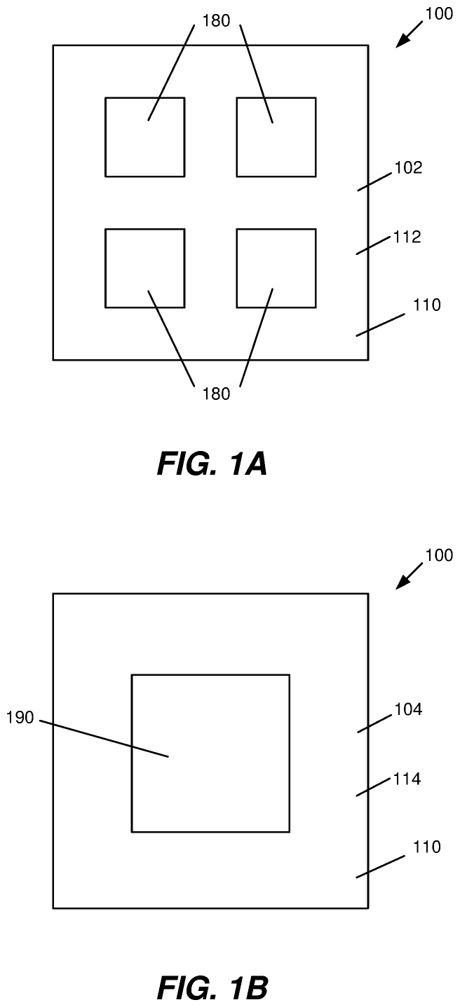

Referring to FIGS. 1A, 1B, an exemplary display tile 100 is schematically depicted. More specifically, FIG. 1A schematically depicts a front plan view of an example of display tile 100, and FIG. 1B schematically depicts a back plan view of an example of display tile 100. Display tile 100 includes a substrate 110, a plurality of light sources 180, and drive circuitry or control electronics 190. Display tile 100 may be part of a multi-tile, arrayed display (e.g., “seamless tiled” display) or may be a single tile, individual display.

In the depicted example, substrate 110 has a first surface 112 (FIG. 1A) and a second surface 114 (FIG. 1B) opposite first surface 112, with light sources 180 provided on first surface 112 and control electronics 190 provided on second surface 114. In examples, first surface 112 represents a front or first side 102 of display tile 100, and second surface 114 represents a back or second side 104 of display tile 100.

Substrate 110 may be formed of glass, glass ceramic, ceramic, or polymer material, or a composite material including different combinations of such materials in a layered or mixture format. In examples, substrate 110 may have a thickness between 0.005 mm and 2 mm, including, more specifically, a thickness between 0.01 mm and 1 mm, between 0.01 mm and 0.7 mm, between 0.05 mm and 0.6 mm, between 0.1 mm and 0.5 mm, or between 0.2 mm and 0.4 mm. In examples, substrate 110 may be rectangular in shape, as illustrated in FIGS. 1A and 1B, or may be of another regular or irregular geometric shape.

Light sources 180 may be arranged, for example, in an array including any number of rows and columns, or other patterns. Each light source 180 is electrically coupled to drive circuitry, such as drive circuitry or control electronics 190, for driving or controlling operation of each light source 180. Control electronics 190 may include, for example, drive ICs, thin film transistors, microDriver ICs, conductors, capacitors, other electrical elements, and/or electrical interconnects or connections. Although illustrated as being provided on second surface 114, in other examples, control electronics 190 (or components thereof) may be provided on first surface 112 (with light sources 180). Each light source 180 may include, for example, a light emitting diode (LED), a microLED, a miniLED, an organic light emitting diode (OLED), or other suitable light source or light modulator, such as a mirror or light valve. In one example, instead of light sources 180 on first surface 102, first surface 102 may be in contact with a liquid crystal cell.

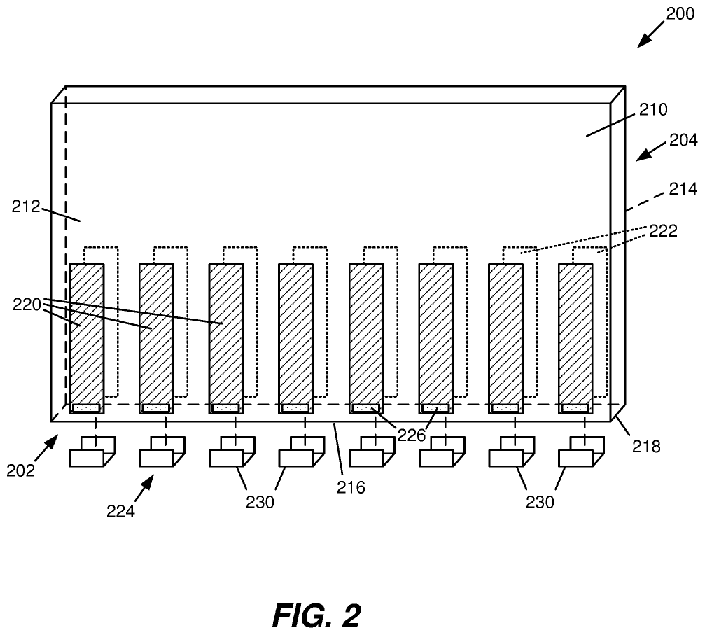

FIG. 2 schematically depicts an exploded perspective view of an example of a substrate 210 for a display tile 200, as an example of substrate 110 for display tile 100, with a plurality of edge conductors 230. Substrate 210 has a first surface 212 and a second surface 214 opposite first surface 212, with light sources (not shown), such as light sources 180 (FIG. 1A), provided on first surface 212 and drive circuitry or control electronics (not shown), such as drive circuitry or control electronics 190 (FIG. 1B), provided on second surface 214. In addition, substrate 210 has a third surface 216 extended between first surface 212 and second surface 214, with third surface 216 representing an edge surface 218 of substrate 210. In examples, drive circuitry or control electronics (or components thereof) may also be provided on first surface 212.

In examples, first surface 212 and second surface 214 are substantially parallel with each other, and edge surface 218 is substantially orthogonal to first surface 212 and second surface 214. In examples, first surface 212 represents a front or first side 202 of display tile 200 and second surface 214 represents a back or second side 204 of display tile 200.

In the depicted example, substrate 210 has a substantially rectangular shape and includes additional edge (or side) surfaces extending between first surface 212 and second surface 214. In other examples, substrate 210 may have other suitable shapes, such as, for example, circular, triangular, or other polygonal shapes, with corresponding or associated surfaces.

In the depicted example, display tile 200 includes first conductors 220 on first surface 212 of substrate 210 and second conductors 222 on second surface 214 of substrate 210. In examples, first conductors 220 are electrically connected to light sources (not shown) provided on first surface 212 of substrate 210, such as light sources 180 (FIG. 1A), and second conductors 222 are electrically connected to drive circuitry or control electronics (not shown) provided on second surface 214 of substrate 210, such as drive circuitry or control electronics 190 (FIG. 1B), for controlling the light sources. In examples, first conductors 220 and second conductors 222 are spaced on respective first surface 212 and second surface 214, and positioned adjacent to and extending inward from edge surface 218.

In one example, an interconnect material 226 is provided adjacent an end of first conductors 220 and second conductors 222 adjacent to edge surface 218. In examples, interconnect material 226 is a conductive material and facilitates electrical connection of edge conductors 230 with first conductors 220 and second conductors 222, as described below. In examples, interconnect material 226 may include a conductive metal, such as, for example, copper, a conductive paste, such as, for example, an anisotropic conductive paste (ACP), a conductive film, such as, for example, an anisotropic conductive film (ACF), or a conductive adhesive, such as, for example, an anisotropic conductive adhesive (ACA). In other examples, in the absence of interconnect material 226, edge conductors 230 may be in direct connection with first conductors 220 and second conductors 222.

Edge conductors 230 represent third conductors 224 of display tile 200, and provide electrical connection between first conductors 220 and second conductors 222, as described below. More specifically, in examples, edge conductors 230 are formed or bent to extend around edge surface 218 of substrate 210 and provide electrical connection between respective and corresponding first conductors 220 on first surface 212 of substrate 210 and second conductors 222 on second surface 214 of substrate 210. In one example, edge conductors 230 are formed of a metal foil, such as a copper foil. In other examples, edge conductors 230 may be formed of a deposited thin conductor film (e.g., Cu, Ag, Au, Mo, ITO, Ni), a multi-layer stack of deposited thin conductor films, or a printed solution-based conductor (e.g., Ag-ink, Cu-ink, carbon nanotube).

As depicted in the example of FIG. 2, edge conductors 230 are aligned with corresponding first conductors 220 provided on first surface 212 of substrate 210 and corresponding second conductors 222 provided on second surface 214 of substrate 210. As such, edge conductors 230 extend between first surface 212 and second surface 214 along edge surface 218 to electrically couple respective first conductors 220 on first surface 212 of substrate 210 with respective second conductors 222 on second surface 214 of substrate 210. Spacing of edge conductors 230 along edge surface 218 may be uniform, as illustrated in the example of FIG. 2, or may vary.

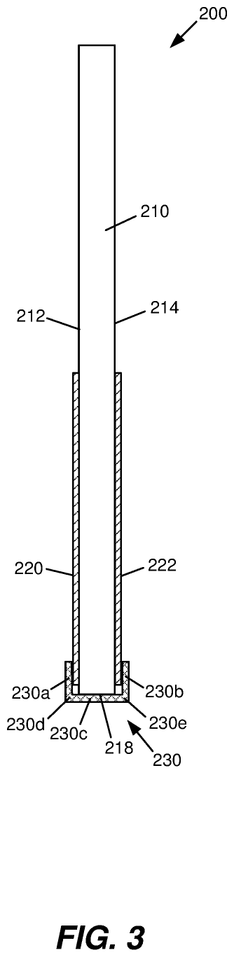

FIG. 3 schematically depicts a side view of an example of edge conductor 230 secured to substrate 210. As depicted in the example of FIG. 3, edge conductor 230 includes a first portion 230a extended along first surface 212, a second portion 230b extended along second surface 214, and a third portion 230c extended along edge surface 218. In addition, edge conductor 230 includes a first bend 230d between first portion 230a and third portion 230c, and a second bend 230e between second portion 230b and third portion 230c.

In one example, with edge conductor 230 formed or bent to extend along first surface 212 and second surface 214, first portion 230a and second portion 230b are substantially parallel with each other. As such, first bend 230d and second bend 230e are each a substantially orthogonal bend (i.e., first bend 230d and second bend 230e are each approximately 90 degrees). In one example, first portion 230a and second portion 230b are substantially the same length such that edge conductor 230 extends substantially the same distance along first surface 212 and second surface 214 of substrate 210. In other examples, first bend 230d and/or second bend 230e may be other than 90 degrees, and, in examples, may be curved (with rounded or smooth profiles), beveled or chamfered. Also, in other examples, first portion 230a, second portion 230b, and/or third portion 230c may be of non-equal lengths, widths, thicknesses or material compositions.

In one example, edge conductors 230 may be pressure bonded to substrate 210. More specifically, first portion 230a of a respective edge conductor 230 may be pressure bonded to a respective first conductor 220 on first surface 212 of substrate 210, and second portion 230b of a respective edge conductor 230 may be pressure bonded to a respective second conductor 222 on second surface 214 of substrate 210. Other manners of securing edge conductors 230 to substrate 210, including, more specifically, first conductor 220 and second conductor 222, may also be implemented.

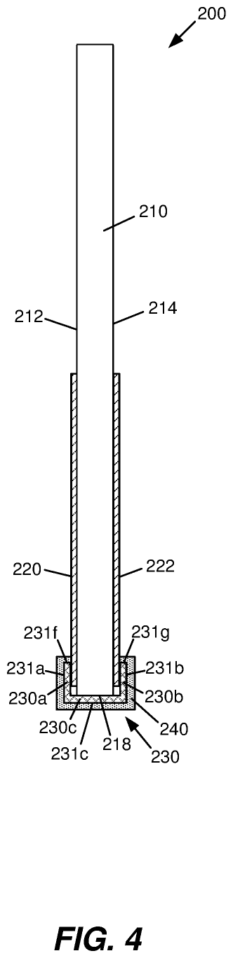

FIG. 4 schematically depicts a side view of an example of edge conductor 230 secured to substrate 210 with a coating 240 over edge conductor 230. In examples, coating 240 may partially cover or entirely cover (e.g., with overage) edge conductor 230, including, more specifically, partially cover or entirely cover (e.g., with overage) first portion 230a, second portion 230b, and/or third portion 230c of edge conductor 230. In examples, coating 240 covers at least a portion of third portion 230c of edge conductor 230. In addition, in examples, coating 240 also covers at least a portion of first portion 230a and second portion 230b of edge conductor 230, including first bend 230d and second bend 230e.

More specifically, as depicted in the example of FIG. 4, coating 240 entirely covers edge conductor 230 and is provided over (previously exposed) surfaces of edge conductor 230. For example, in one implementation, coating 240 is provided over (previously exposed) surfaces 231a, 231b, and 231c of first portion 230a, second portion 230b, and third portion 230c, respectively, as well as (previously exposed) end surfaces 231f and 231g of first portion 230a and second portion 230b, respectively. As such, coating 240 covers, protects, encapsulates, and/or conceals edge conductor 230. As described below, coating 240 may provide mechanical advantage(s) and/or optical advantage(s).

As illustrated in the example of FIG. 4, coating 240 covers equal lengths of first portion 230a and second portion 230b and is of uniform thickness over first portion 230a, second portion 230b and third portion 230c. In other examples, coating 240 may cover unequal lengths of first portion 230a and second portion 230b, and may be of non-uniform (or unequal) thickness over first portion 230a, second portion 230b and/or third portion 230c such that a thickness of coating 240 varies over first portion 230a, second portion 230b and/or third portion 230c. In examples, coating 240 may be symmetrically aligned with edge surface 218 and, in other examples, may be asymmetrical with edge surface 218 (i.e., offset and closer to first surface 212 or second surface 214). In examples, coating 240 may be excluded from first portion 230a and/or second portion 230b.

Mechanical advantage(s) of coating 240 include helping to protect edge conductors 230 (as well as edge surface 218 of substrate 210) from damage. This may include protection of edge conductors 230 (as well as edge surface 218) from contact, scratches, indents, mechanical shock, chipping, and/or peeling. In addition, coating 240 may serve as a barrier for environmental contaminants such as corrosion, dust, and/or moisture (which could degrade performance of edge conductors 230). Coating 240 may also enhance the overall mechanical strength of display tile 200. Accordingly, coating 240 helps to improve reliability of display tile 200 by protecting edge conductors 230 (as well as edge surface 218).

Optical advantage(s) of coating 240 include helping to suppress or prevent optical reflection or scattering from edge conductors 230 (as well as edge surface 218 of substrate 210). By minimizing or eliminating unwanted reflection or light scattering from edge conductors 230 (as well as edge surface 218 of substrate 210), coating 240 helps to prevent optical defects and/or avoid generation of interfering images. To provide the noted optical advantage(s), coating 240 may include an optically absorbing coating and/or film. As an optically absorbing coating and/or film, coating 240 absorbs or “traps” light that may otherwise be reflected or scattered from edge conductors 230 (and/or edge surface 218 of substrate 210). As such, coating 240 may cause incident light to either be absorbed or scattered (diffused) away from the viewer. In examples, coating 240 includes an optically absorbing ink. In examples, the optically absorbing ink may have an Optical Density (OD) of >0.5, >1, >1.5, >2, >3, >4, >4.5, >5, or >10 in the visible spectrum of 400-800 nm wavelength range.

In examples, coating 240 may be a clear coating or film, or a non-clear coating or film. In examples, coating 240 may be solvent containing or solvent-free, and may be solvent resistant and chemically/mechanically durable. Coating 240 may contain organics, inorganics, or hybrid materials, including polymers and resins such as acrylates, urethanes, epoxies, silicones and the like, with various possible combinations of binders and solvents. Coating 240 may contain particles of various sizes, i.e., nanoparticles or micro-sized particles, plasticizers and pigments of various colors. Coating 240 may contain additives to enhance adhesion, reduce vaporization of solvents, and/or adjust viscosity. In examples, coating 240 may contain coloring pigments.

In examples, coating 240 is (generally and preferably) non-conductive (i.e., has a high resistance and is not able to conduct electricity) to prevent electrical shorting between adjacent edge conductors 230. In one implementation, coating 240 is an optically absorbing non-conductive black ink. In examples, a thickness of coating 240 may range, for example, from 50 nm to 100 um. In examples, a thickness of coating 240 may range, for example, from 2 um to 50 um. In examples, as coating may be exposed to high temperatures (e.g., 50 degrees C., <100 degrees C., <150 degrees C., <200 degrees C., <250 degrees C., <300 degrees C., <350 degrees C.), coating 240 may be thermally stable.

In examples, coating 240 may include a single layer or multiple layers. In one implementation, coating 240 may be a multi-layer stack, with one layer (or component) of coating 240 being non-conductive and another layer (or component) of coating 240 being optically absorbing. For example, a first, optically transparent, comparably thin (e.g., <1 um thick), non-conductive layer may be applied over (i.e., in contact with) edge conductors 230, and a second, comparably thicker (e.g., >1 um thickness), optically absorbing, possibly electrically conductive layer, may be applied over (i.e., in contact with) the first layer. In examples, thickness, electrical resistivity, optical absorption, hardness, and Young's modulus of the multiple layers may vary.

Coating 240 may be applied, for example, by dipping, rolling, spraying, printing, jetting, moving fibers, brushing, powder-coating, sintering, or other techniques. In addition, coating may be air dried, oven dried, UV cured, IR cured, or dried and cured by a combination thereof. Drying or curing may be incorporated in-line as part of the coating process or may be performed off-line separately from the coating process. In examples, coating 240 may be applied using plasma deposition, chemical vapor deposition (CVD), physical vapor deposition (PVD), or other deposition techniques.

In examples, coating 240 conforms to an edge profile of substrate 210 and a profile or shape of edge conductors 230. Although illustrated as having an orthogonal edge profile, substrate 210 may have another edge profile, such as a beveled or chamfered profile or a non-straight profile, such as curved, rounded, wavy or oscillating. In addition, the edge of substrate 210 may be straight along its length or have a sinusoidal or other non-linear shape.

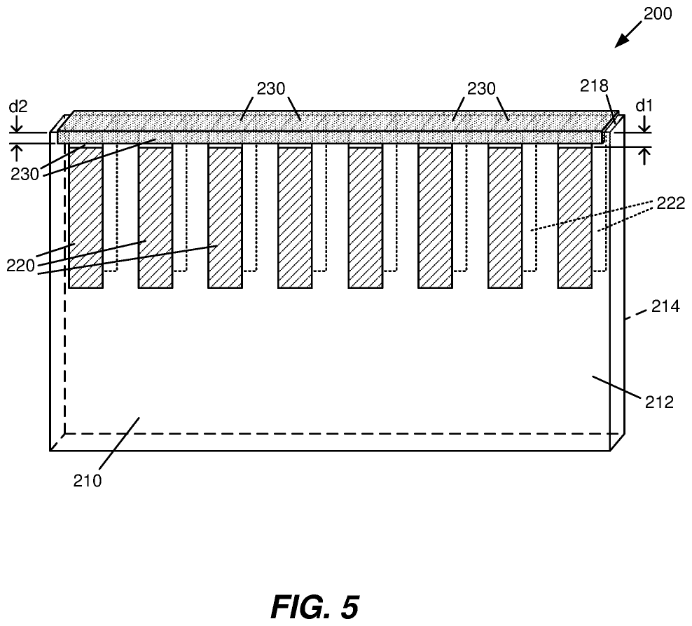

FIG. 5 schematically depicts a perspective view of an example of substrate 210 with edge conductors 230 and coating 240 over edge conductors 230. More specifically, as depicted in the example of FIG. 5, coating 240 extends over multiple edge conductors 230 and covers edge surface 218 of substrate 210 between adjacent edge conductors 230. As such, in examples, coating 240 is continuous along edge surface 218 of substrate 210. In other examples, coating 240 may be patterned or non-continuous along edge surface 218 of substrate 210 such that coating 240 only exists over respective edge conductors 230. Also, in examples, coating 240 may be thinner, thicker, or of substantially similar thickness as edge conductors 230. In examples, coating 240 may conformably cover, be discontinuous, or provide a planarized surface along edge surface 218 of substrate 210. For example, a thickness of coating 240 may be different over edge conductor 230 as compared to between adjacent edge conductors 230.

In one example, as depicted in the example of FIG. 5, coating 240 extends beyond edge surface 218 to cover a portion of edge conductors 230 extended along first surface 212 and second surface 214. In one example, coating 240 also covers a portion of first surface 212 and a portion of second surface 214 adjacent and/or between respective edge conductors 230. In one example, edge conductors 230 extend a distance (d1) along first surface 212 and second surface 214 of substrate 210, and coating 240 has an overflow dimension (d2), where overflow dimension (d2) is less than distance (d1). In examples, coating 240 may have an overflow dimension (d2) of <25 um, <50 um, <100 um, <200 um, <500 um (or more) or within this range.

In examples, only one edge or multiple edges (e.g., two edges, three edges, all edges) of substrate 210 may include edge conductors 230. As such, coating 240 be applied to any edges including edge conductors 230. Coated edges may be dried or cured one edge at a time, after coating a specific edge, or after coating all desired edges.

In one example, coating 240 includes an ink, and is applied by printing, including, more specifically, screen-printing. With such a printing method, single or multiple layers of coating 240 may be applied using single or multiple composition of inks. As such, hybrid coating or film structures of various thicknesses may be created. The ink of coating 240 may be clear or colored, may be optically absorbing, may consist of multiple layers, may thermal or UV curable, and/or may include a composition containing organics, inorganics or hybrid materials. In addition, the ink of coating 240 may be tuned to achieve certain print thickness, optical density (OD), resistivity, and/or other print features.

In one example, coating 240 is applied to a stacked series of display tiles 200 using a vertical-form screen-printing approach. More specifically, multiple display tiles, such as display tiles 200 with substrates 210 and edge conductors 230, are arranged horizontally and aligned vertically such that edge surfaces 218 of adjacent substrates 210, with edge conductors 230, are exposed. As such, coating 240 may be applied to edge conductors 230 and/or edge surfaces 218 of substrates 210.

The disclosed printing method may be used to apply coating 240 continuously along edge surface 218, for example, from one end to an opposite end, or may be used to apply coating 240 in a pattern, including, for example, only over edge conductors 230. The disclosed printing method helps to enable uniform printing along edge surface 218, and may be used with rigid, semi-rigid, semi-flexible and flexible substrates. The disclosed printing method may also be used for variety of substrate compositions and dimensions. With the vertical-form screen-printing approach disclosed herein, coating 240 may be applied to a single display tile or multiple display tiles at one time.

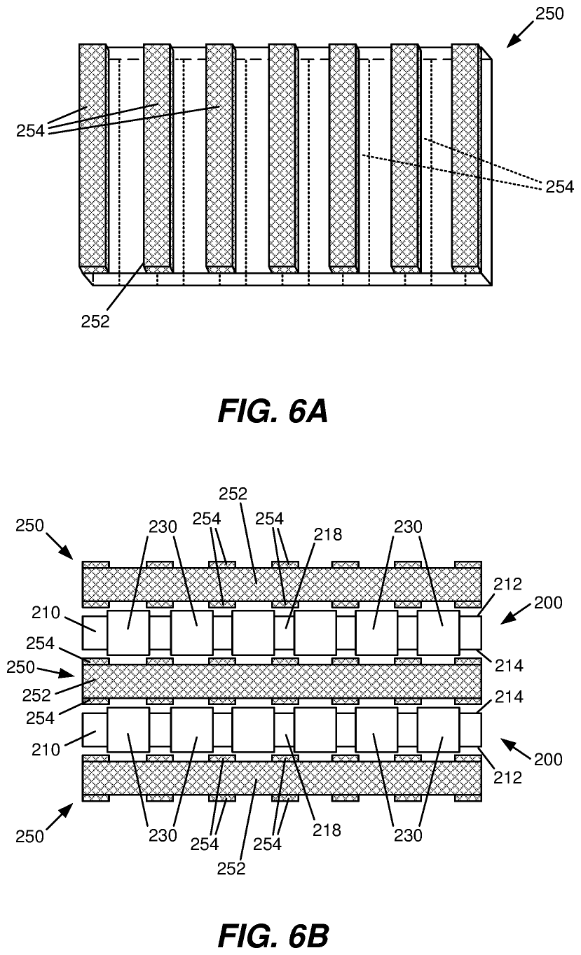

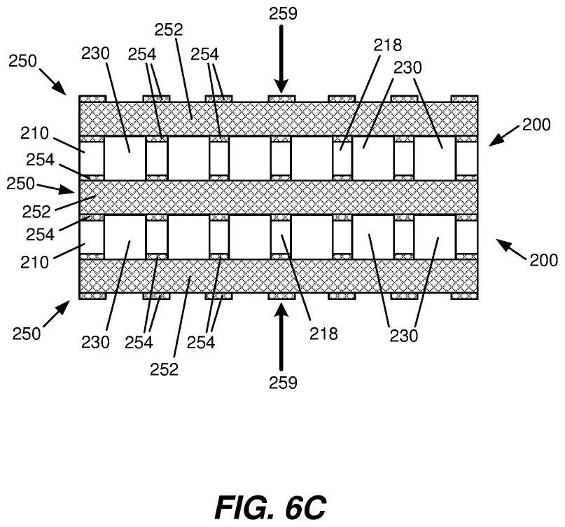

FIGS. 6A, 6B, 6C schematically depict an example of spacers 250 which may be used when applying coating 240 to multiple display tiles 200 at one time. In examples, spacers 250 may be flat, wavy, or include protruding or raised features or elements, and may be compliant and become conformal when pressed or compressed. For example, as described below, spacers 250 may conform to display tiles 200 when positioned between display tiles 200 of a stacked series of display tiles 200.

In one implementation, as schematically illustrated in FIG. 6A, spacers 250 include a substrate 252 and a plurality of spacer features or elements 254 patterned, supported, or formed by and/or on substrate 252. In one implementation, spacer features or elements 254 are provided on opposite sides of substrate 252 (such that one spacer 250 may be positioned between two adjacent display tiles 200). Although illustrated as being rectangular in shape, spacer features or elements 254 may be of other shapes, sizes, or geometries. For example, spacer features or elements 254 may be of a border or frame (i.e., “picture frame”) shape so as to surround first conductors 220 (or second conductors 222) on first surface 212 (or second surface 214).

In examples, spacer elements 254 are spaced along substrate 252 corresponding to a spacing of edge conductors 230 along edge surface 218. In addition, in examples, spacer elements 254 have a thickness corresponding to (or greater than) a thickness of edge conductors 230. As such, in examples, spacers 250, including, more specifically, spacer elements 254, account for gaps between adjacent edge conductors 230 along first surface 212 (or second surface 214) of substrate 210.

In one implementation, as schematically illustrated in FIG. 6B, spacers 250 are positioned between adjacent substrates 210 to align and/or space multiple display tiles 200 for coating at one time. As such, in examples, spacers 250 account for gaps between adjacent substrates 210 due to a thickness of edge conductors 230 along first surface 212 (or second surface 214), and a thickness of first conductors 220 (or second conductors 222) on first surface 212 (or second surface 214). In examples, spacers 250 help to control or reduce possible overflow and/or capillary-action-driven ink leakage between adjacent tiles 200 when applying coating 240 to multiple display tiles 200 at one time. Spacers 250 also may be placed on outer sides of the stacked substrates 210. In examples, spacers 250 also provide support and/or protection to display tiles 200 during subsequent processing, handling, and/or transporting of display tiles 200, including, for example, drying, curing, post-processing, and/or shipping.

In one example, as schematically illustrated in FIG. 6C, to help control and/or maintain alignment of adjacent substrates 210, pressure (e.g., normal to first surface 212 and second surface 214) may be applied to a stacked series of display tiles 200 (represented, for example, by arrows 259). In one implementation, with spacers 250 between adjacent substrates 210, spacers 250 may conform to a shape of edge conductors 230 and first conductors 220 (or second conductors 222) when pressure is applied to an arranged tile stack. For example, spacers 250 may be sized to contact (and conform) to edge conductors 230 and first conductors 220 (or second conductors 222), including, more specifically, high points of edge conductors 230 and first conductors 220 (or second conductors 222). In other examples, spacers 250 may be sized to provide additional space around edge conductors 230 and first conductors 220 (or second conductors 222) (i.e., avoid direct contact with edge conductors 230 and first conductors 220 (or second conductors 222)).

In examples, spacers 250 may include rigid, semi-rigid, semi-flexible, flexible, compressible, and/or incompressible films, layers, and/or components, including, for example, plates, disks, gaskets, posts, tape, etc. In examples, spacers 250 may include adhesive, flowable, curable, removable, dissolvable, soluble, and/or temporary films, layers, and/or components, including, for example, plates, disks, gaskets, posts, tape, etc. In examples, spacers 250 may be single-use, multi-use, and/or reusable.

In examples, a clamp, fixture, tape or other retention or supporting element may be used to temporarily hold the stacked substrates 210 during the printing process. In one example, to help control or reduce ink leakage between adjacent tiles 200, a vacuum-based system may be used to assist with and/or control ink flow.

In examples, as described below, a fixture (or fixtures) may be used to enable the vertical-form printing. More specifically, a fixture (or fixtures) may be used to hold one or multiple display tiles 200 to enable printing on edge surface 218 and over edge conductors 230. In examples, a fixture (or fixtures) may be used to hold and/or align multiple display tiles 200 in a parallel manner to enable printing on multiple display tile edges at the same time.

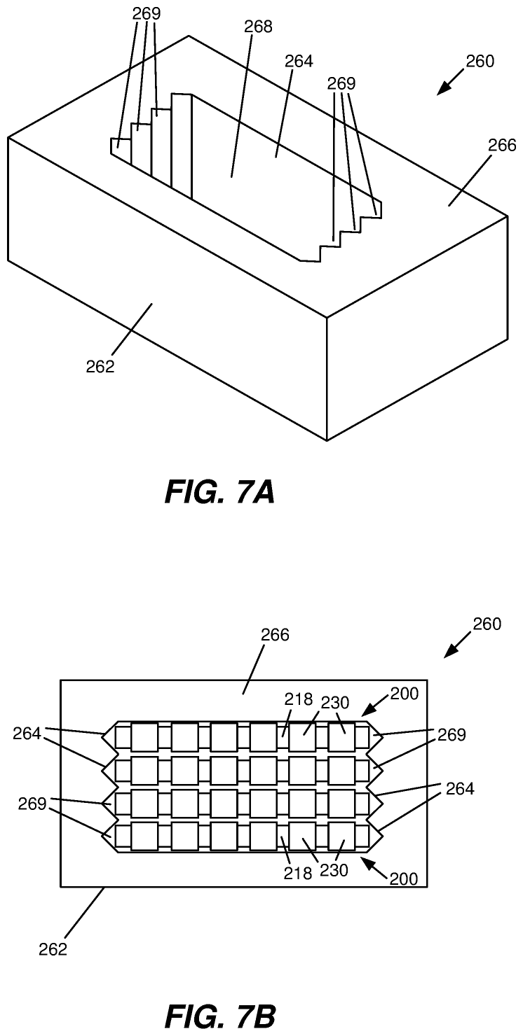

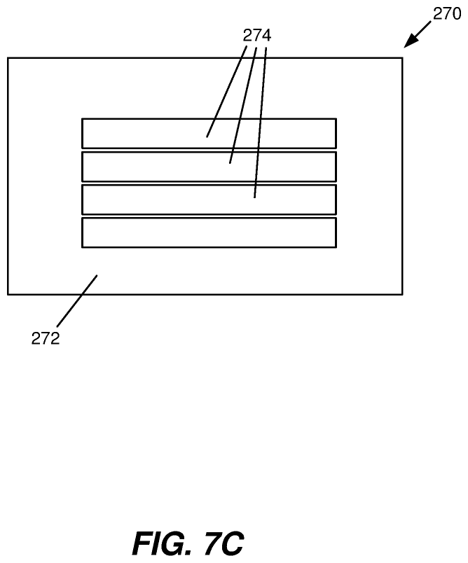

FIGS. 7A, 7B, 7C schematically depict an example of a fixture 260 which may be used when applying coating 240 to one or more display tiles 200. As illustrated in the example of FIGS. 7A, 7B, fixture 260 includes a block 262 with one or more slots 264 formed in a surface 266 of block 262. In examples, fixture 260 may hold one or more display tiles 200 per slot 264 in a parallel manner. As such, slots 264 hold or constrain display tiles 200 for processing, as disclosed herein.

In the illustrated example, block 262 of fixture 260 includes an opening 268 with opposite grooved edges 269. As such, in one example, each slot 264 is formed by a pair of opposite grooved edges 269. In examples, a depth of slots 264 and/or a height of fixture 260 is such that edge conductors 230, along respective edge surfaces 218, are coplanar with surface 266 when display tiles 200 are positioned in slots 264 of fixture 260. As such, fixture 260 enables printing on parallelly aligned display tile edges. In examples, a print direction is parallel with a length of slots 264.

In examples, fixture 260 may be used to support and/or hold display tiles 200 (with or without spacers such as, for example, spacers 250) during processing, handling, and/or transporting of display tiles 200, including, for example, printing, coating, drying, curing, post-processing, and/or shipping. As such, in examples, fixture 260 helps to prevent display tiles from rubbing together, which could potentially damage the tiles.

As illustrated in the example of FIG. 7C, a printing screen or stencil 270 may be used when applying coating 240. In examples, stencil 270 includes a panel or frame 272 with parallel slots 274 formed therethrough. Accordingly, panel or frame 272 may be positioned on surface 266 of fixture 260 (FIG. 7A, 7B) such that slots 274 align with edge surfaces 218 of substrates 210 (with edge conductors 230). As such, coating 240 may be applied to edge surfaces 218 of substrates 210, and edge conductors 230, through slots 274. In examples, when using stencil 270, a print direction is parallel with a length of slots 274. Although fixture 260 is illustrated as including four slots 264 (for holding four display tiles 200) and stencil 270 is illustrated as including four slots 274, the number of slots 264 and slots 274 may vary.

In examples, dimensions of fixture 260, including slots 264, may be adjusted to accommodate different sizes and shapes of display tiles 200. In addition, dimensions of stencil 270, including slots 274, may be adjusted to accommodate a variety of sizes and shapes of display tiles 200.

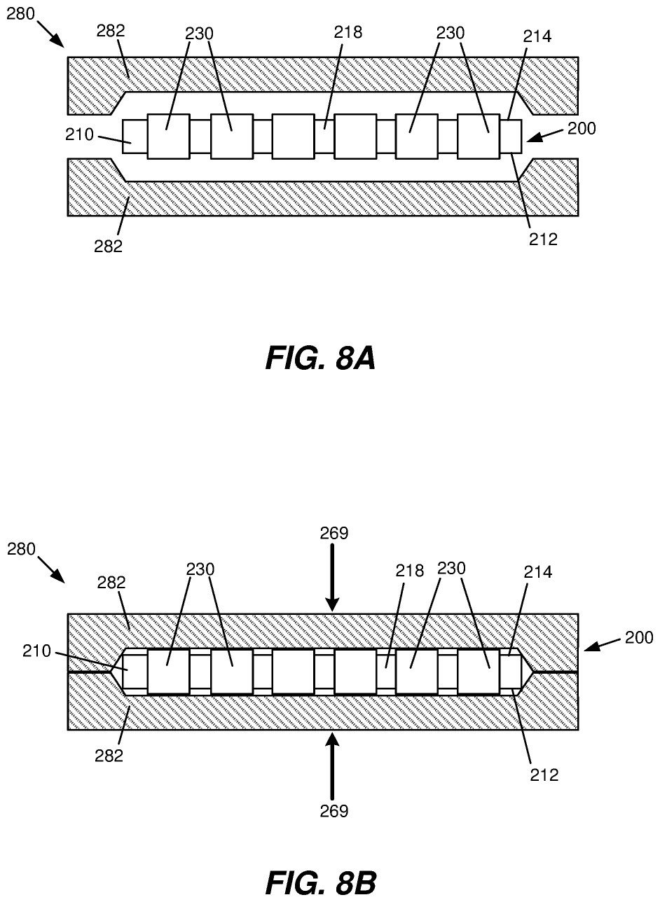

FIGS. 8A, 8B schematically depict an example of a fixture 280 which may be used when applying coating 240 to one or more display tiles 200. As illustrated in the example of FIGS. 8A, 8B, fixture 280 includes a pair of retaining or alignment blocks 282 that clamp or hold one or more display tiles 200 therebetween. In examples, at least one of the alignment blocks 282 may be moved relative to the other alignment block 282 to secure or sandwich display tile(s) 200 therebetween. More specifically, in one implementation, at least one of the alignment blocks 282 may be moved relative to the other alignment block 282 in a direction perpendicular to first surface 212 and second surface 214 (as represented, for example, by arrows 269) to clamp or hold display tile(s) 200 therebetween. In examples, multiple display tiles 200 may be stacked together, with spacers (for example, spacers 250, as illustrated in FIGS. 6A, 6B, 6C) therebetween or at ends of the stack thereof, and placed between alignment blocks 282. In examples, with fixture 280, a printing screen or stencil (such as, for example, printing screen or stencil 270) may be used to apply coating 240 to display tile(s) 200. In examples, a print direction is parallel with a length of alignment blocks 282.

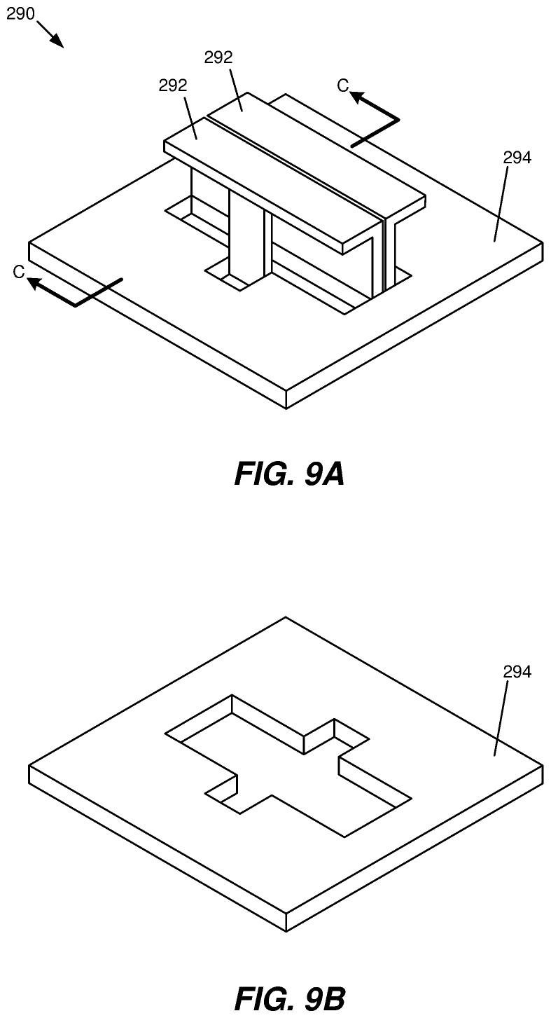

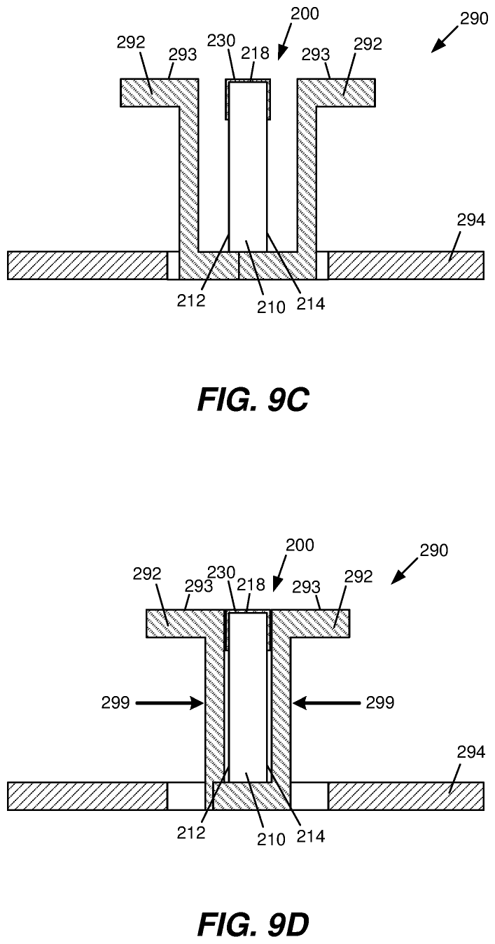

FIGS. 9A, 9B, 9C, 9D schematically depict an example of a fixture 290 which may be used when applying coating 240 to one or more display tiles 200, with FIGS. 9C, 9D being schematic cross-sectional views from the perspective of C-C of FIG. 9A. As illustrated in the example of FIGS. 9A, 9B, 9C, 9D, fixture 290 includes a pair of retaining or alignment blocks 292 that clamp or hold one or more display tiles 200, with edge conductors 230, therebetween. In one example, as illustrated in FIG. 9B, alignment blocks 292 are positioned on or in a bottom plate 294.

In one example, as illustrated in FIGS. 9C, 9D, at least one of the alignment blocks 292 may be moved relative to the other alignment block 292 to secure or sandwich display tile(s) 200 therebetween. More specifically, in one implementation, at least one of the alignment blocks 292 may be moved relative to the other alignment block 292 in a direction perpendicular to first surface 212 and second surface 214 (as represented, for example, by arrow 299) to clamp or hold display tile(s) 200 therebetween. In examples, a height of alignment blocks 292 is such that edge conductors 230, along respective edge surfaces 218, are coplanar with a top surface 293 of alignment blocks 292 when display tiles 200 are positioned in fixture 290. In examples, multiple display tiles 200 may be stacked together, with spacers (for example, spacers 250, as illustrated in FIGS. 6A, 6B, 6C) therebetween or at ends of the stack thereof, and placed between alignment blocks 292. In examples, with fixture 290, a printing screen or stencil (such as, for example, printing screen or stencil 270) may be used to apply coating 240 to display tile(s) 200. In examples, a print direction is parallel with a length of alignment blocks 292.

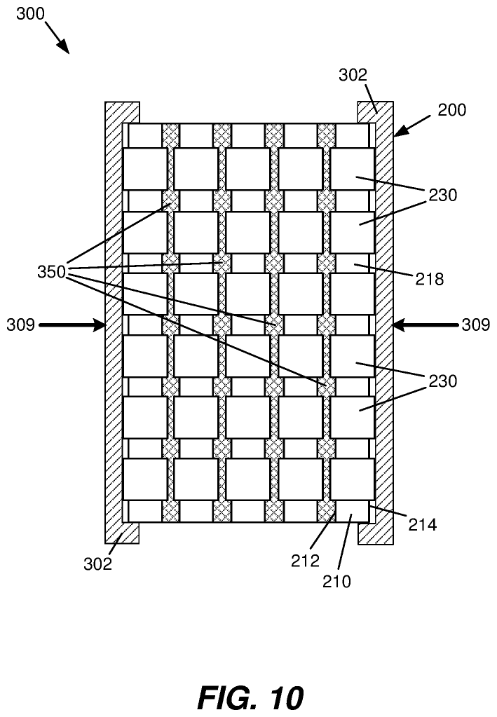

FIG. 10 schematically depicts an example of a fixture 300 which may be used when applying coating 240 to one or more display tiles 200. As illustrated in the example of FIG. 10, fixture 300 includes a pair of retaining or alignment blocks 302 that clamp or hold one or more display tiles 200 therebetween. In one implementation, at least one of the alignment blocks 302 may be moved relative to the other alignment block 302 in a direction perpendicular to first surface 212 and second surface 214 (as represented, for example, by arrow 309) to clamp or hold display tile(s) 200 therebetween. In examples, multiple display tiles 200 may be stacked together and placed between alignment blocks 302. In one example, spacers, such as spacers 350, may be positioned between (and conform to) adjacent display tiles 200. In examples, with fixture 300, a printing screen or stencil (such as, for example, printing screen or stencil 270) may be used to apply coating 240 to display tile(s) 200. In examples, a print direction is parallel with a length of alignment blocks 302.

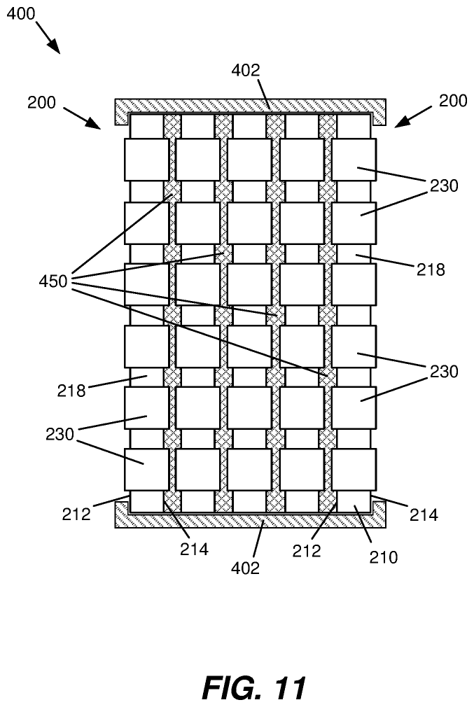

FIG. 11 schematically depicts an example of a fixture 400 which may be used when applying coating 240 to multiple display tiles 200. As illustrated in the example of FIG. 11, fixture 400 includes a pair of alignment or retaining elements 402 that hold or retain a stack of display tiles 200 therebetween. In one implementation, retaining elements 402 extend or wrap from first surface 212 (or second surface 214) of a first display tile 200 of the stack, along adjacent ends of display tiles 200 of the stack, to second surface 214 (or first surface 212) of a last display tile 200 of the stack. As such, in one example, retaining elements 402 represent end bindings that hold, retain and/or align display tiles 200 along the ends thereof. In one implementation, retaining elements 402 are formed of a binding material, such as tape. In one example, spacers, such as spacers 450, may be positioned between (and conform to) adjacent display tiles 200. In examples, with fixture 400, a printing screen or stencil (such as, for example, printing screen or stencil 270) may be used to apply coating 240 to display tile(s) 200. In examples, a print direction is perpendicular to a length of retaining elements 402 from one end of the display tiles 200 of the stack to an opposite end of the display tiles 200 of the stack.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein.

1. An edge conductor, comprising:
a first portion electrically connected to a first conductor on a first surface of a substrate;
a second portion electrically connected to a second conductor on a second surface of the substrate, the second surface of the substrate opposite the first surface of the substrate;
a third portion extending between the first portion and the second portion and extending along an edge of the substrate, the edge of the substrate extending between the first surface of the substrate and the second surface of the substrate; and
a coating covering at least a portion of the third portion of the edge conductor.

2. The edge conductor of claim 1, wherein the first portion and the second portion of the edge conductor are substantially parallel with each other, and wherein the coating further covers at least a portion of the first portion of the edge conductor and at least a portion of the second portion of the edge conductor.

3. The edge conductor of claim 1, wherein the coating conforms to a shape of the edge conductor.

4. The edge conductor of claim 1, wherein the coating is optically absorbing.

5. The edge conductor of claim 1, wherein the coating comprises a non-conductive layer applied over the edge conductor, and an optically absorbing layer applied over the non-conductive layer.

6. The edge conductor of claim 1, further comprising:
a first bend between the first portion and the third portion of the edge conductor; and
a second bend between the second portion and the third portion of the edge conductor,
wherein the first bend and the second bend are substantially orthogonal,
wherein the coating further covers at least the first bend and the second bend.

7. The edge conductor of claim 1, wherein the coating further covers the edge of the substrate adjacent the edge conductor.

8. The edge conductor of claim 1, wherein the coating conforms to a shape of the edge conductor.

9. The edge conductor of claim 1, wherein the edge conductor comprises metal foil, and wherein the coating comprises a non-conductive layer.

10. A display tile, comprising:
a substrate having a first surface, a second surface opposite the first surface, and an edge surface extending between the first surface and the second surface;
a first conductor on the first surface of the substrate;
a second conductor on the second surface of the substrate;
a third conductor extending along each of the first surface, the second surface, and the edge surface; and
a coating covering at least a portion of the third conductor along the edge surface,
wherein the third conductor is electrically coupled with both the first conductor and the second conductor.

11. The display tile of claim 10, wherein the coating further covers at least a portion of the third conductor along the first surface of the substrate and at least a portion of the third conductor along the second surface of the substrate.

12. The display tile of claim 10, wherein the coating is optically absorbing.

13. The display tile of claim 10, wherein the coating further covers the edge surface of the substrate adjacent the third conductor.

14. The display tile of claim 13, wherein the coating conforms to the third conductor and the edge surface of the substrate.

15. A method of making a display tile, comprising:
forming an edge conductor to extend along a first surface of a substrate, a second surface of the substrate opposite the first surface of the substrate, and an edge surface of the substrate, the edge surface extending between the first surface of the substrate and the second surface of the substrate; and
coating at least a portion of the edge conductor along the edge surface of the substrate.

16. The method of claim 15, further comprising:
electrically coupling the edge conductor with a first conductor on the first surface of the substrate and a second conductor on the second surface of the substrate, and
wherein coating the edge conductor further comprises coating at least a portion of the edge conductor along the first surface of the substrate and the second surface of the substrate.

17. The method of claim 15, wherein coating the edge conductor comprises mechanically protecting the edge conductor.

18. The method of claim 15, wherein coating the edge conductor comprises coating the edge conductor with an optically absorbing coating.

19. The method of claim 18, wherein coating the edge conductor comprises conforming the coating to the edge conductor.

20. The method of claim 15, wherein coating the edge conductor comprises coating the edge surface of the substrate adjacent the edge conductor.
